(19) United States
(12) Patent Application Publication
(10) Pub. No.: US 2009/0109761 A1
(43) Pub. Date: Apr. 30, 2009

(54) Method of operating nonvolatile memory device

(75) Inventors: Young-gu Jin, Hwaseong-si (KR); Won-joo Kim, Hwaseong-si (KR); Suk-pil Kim, Yongin-si (KR); Yoon-dong Park, Yongin-si (KR); Seung-hoon Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/076,310

(22) Filed: Mar. 17, 2008

(30) Foreign Application Priority Data
Oct. 24, 2007 (KR) 10-2007-0107431

(51) Int. Cl. G11C 16/20

(52) U.S. Cl. 365/185.24; 365/185.17; 365/185.28

(57) ABSTRACT

Provided is a method of operating a three-dimensional nonvolatile memory device which may increase the reliability and efficiency of the three-dimensional nonvolatile memory device. The method of operating a nonvolatile memory device may include: resetting the nonvolatile memory device by injecting charges into charge storage layers of a plurality of memory cells of a block; and setting the nonvolatile memory device by removing at least some of the charges injected into the charge storage layers of one or more memory cells selected from among the plurality of memory cells.

### PRIORITY STATEMENT

This application claims priority under 35 U.S.C. §119 to Korean Patent Application No. 10-2007-0107431, filed on Oct. 24, 2007, in the Korean Intellectual Property Office, the entire contents of which are incorporated herein by reference.

### BACKGROUND

1. Field

Example embodiments may relate to a semiconductor device, and more particularly, to a method of operating a three-dimensional nonvolatile memory device.

2. Description of Related Art

Current semiconductor products may become increasingly miniaturized and may also be required to operate at higher speeds. Thus, highly integrated non-volatile memory devices having excellent performance may be desirable for use as semiconductor products. Three-dimensional non-volatile memory devices may be used instead of conventional planar type non-volatile memory devices. Three-dimensional non-volatile memory devices may have a larger channel area than conventional planar type non-volatile memory devices and thus may operate at higher speeds.

However, source and drain areas may still occupy a large portion of three-dimensional non-volatile memory devices. NAND type non-volatile memory devices may use a serial arrangement structure to attain comparatively high integration. However, an increase in integration of NAND type non-volatile memory devices may be limited due to source and drain areas which may still occupying a large portion of NAND type non-volatile memory devices.

Furthermore, three-dimensional non-volatile memory devices may have a different electric field distribution compared to conventional planar type non-volatile memory devices. Hence, an application of a method of operating conventional planar type non-volatile memory devices to three-dimensional non-volatile memory devices may reduce operating reliability and efficiency of three-dimensional non-volatile memory devices.

### SUMMARY

Example embodiments may provide a method of operating a three-dimensional nonvolatile memory device for increasing the reliability and efficiency of the three-dimensional nonvolatile memory device.

Example embodiments may provide a method of operating a nonvolatile memory device which may comprise: resetting the nonvolatile memory device by injecting charges into charge storage layers of a plurality of memory cells of a block; and setting the nonvolatile memory device by removing at least some of the charges injected into the charge storage layers of one or more memory cells selected from among the plurality of memory cells.

The resetting of the nonvolatile memory device may comprise applying a negative resetting voltage to control gate electrodes of the plurality of memory cells, and applying a positive resetting voltage to a body of the plurality of memory cells.

The setting of the nonvolatile memory device may comprise applying a positive setting voltage to control gate electrodes of the one or more selected memory cells.

The setting and resetting of the nonvolatile memory device may further comprise tunneling the charges between the charge storage layers and control gate electrodes that may be coupled to the charge storage layers.

Example Embodiments may provide a method of operating a nonvolatile memory device which may comprise: a semiconductor substrate; a plurality of control gate electrodes which may be recessed into the semiconductor substrate; a plurality of tunneling insulation layers which may be disposed between the plurality of charge storage layers and the semiconductor substrate, pairs of adjacent tunneling insulation layers which may be contacting each other and may be separating the semiconductor substrate into first and second regions; and a plurality of blocking insulation layers which may be disposed between the plurality of charge storage layers and the plurality of control gate electrodes. The method may comprise: resetting the nonvolatile memory device by injecting charges into the plurality of charge storage layers; and setting the nonvolatile memory device by removing at least some of the charges injected into one or more charge storage layers selected from the plurality of charge storage layers.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a flowchart illustrating a method of operating a nonvolatile memory device according to example embodiments.

FIG. 2 is a graph for explaining a method of operating a single level cell (SLC) according to example embodiments.

FIG. 3 is a graph for explaining a method of operating a multi level cell (MLC) according to example embodiments.

FIG. 4 is a circuit diagram of a nonvolatile memory device illustrating a resetting operation in a method of operating the nonvolatile memory device according to example embodiments.

FIG. 5 is a circuit diagram of a nonvolatile memory device illustrating a resetting operation in a method of operating the nonvolatile memory device according to example embodiments.

FIG. 6 is a circuit diagram of a nonvolatile memory device illustrating a setting operation in a method of operating the nonvolatile memory device according to example embodiments.

FIG. 7 is a plan view of a non-volatile memory device illustrating a method of operating the non-volatile memory device according to example embodiments.

FIG. 8 is a partial perspective view of the non-volatile memory device illustrated in FIG. 7.

FIG. 9 is a graph illustrating the distribution of electric fields in an operation of setting the nonvolatile memory device illustrated in FIGS. 7 and 8 according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

According to example embodiments, non-volatile memory devices may have a three-dimensional structure. For example, non-volatile memory devices according to example embodiments may have recessed control gate electrodes inside a semiconductor substrate. These non-volatile memory devices may be classified into recess type or trench type non-volatile memory devices. However, example embodiments may be applied to other types of memory devices.

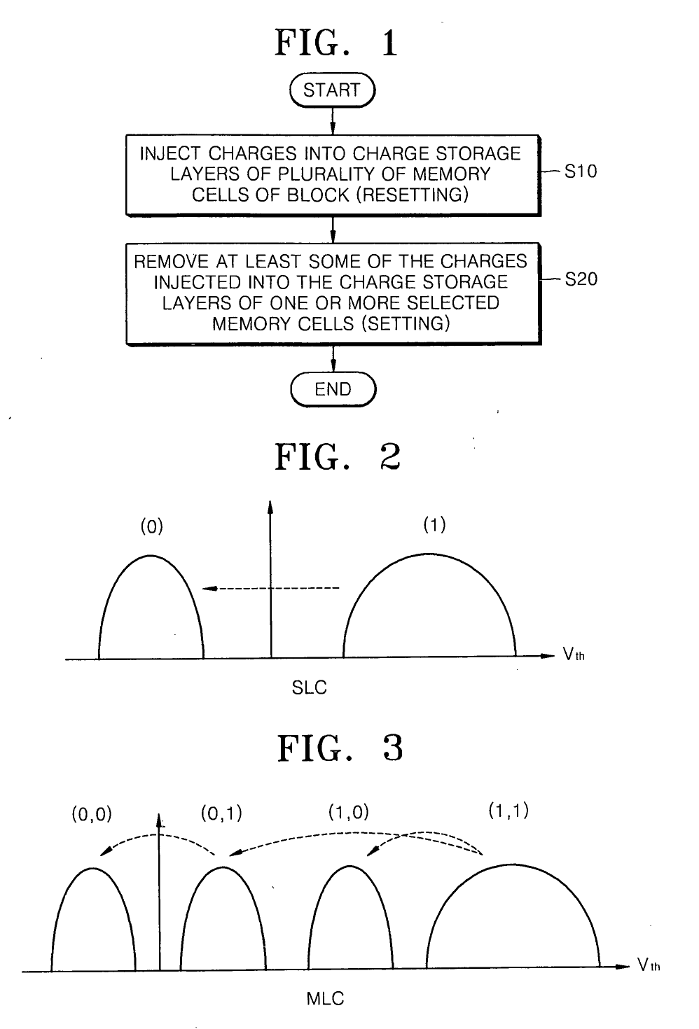

FIG. 1 is a flowchart illustrating a method of operating a nonvolatile memory device according to example embodiments. According to example embodiments, a block may include a plurality of memory cells in a NAND structure.

Referring to FIG. 1, resetting operation S10 may comprise injecting charges into charge storage layers of the plurality of memory cells of the block. Resetting operation S10 may be used to initialize memory cells, and may be different from a general resetting operation that may be performed by removing charges from the charge storage layers. According to example embodiments, in resetting operation S10, data may be reset (or erased) even if the charges are injected into the charge storage layers.

Setting operation S20 may include removing at least some charges injected into a charge storage layer of one or more memory cells that may be selected from among reset memory cells. In setting operation S20, a data state may be stored in the memory cells. Setting operation S20 may be different from a general setting operation that may be performed by injecting charges into the charge storage layers. According to example embodiments, data may be programmed even if the charges injected into the charge storage layer are removed.

Therefore, resetting and setting operations S10 and S20 may operate in an inverse manner compared to a general method of operating a nonvolatile memory device. Data programming and data erasure in example embodiments may be performed in an inverse manner when compared to a general method of operating a nonvolatile memory device.

As will be described later, the operation method of the present embodiment may be useful for tunneling conditions in which a blocking insulating layer may be preferential to a tunneling insulating layer. According to the general operation method, charges may travel between channels and charge storage layers via tunneling, whereas in the operation method according example embodiments, charges may travel between charge storage layers and control gate electrodes via tunneling.

FIG. 2 is a graph illustrating a method of operating a single level cell (SLC) according to example embodiments. Referring to FIG. 2, in a method of operating the SLC according to example embodiments, one bit data states may be indicated as (0) and (1). The upper data state (1) may have a higher threshold voltage Vₜₕ than that of the lower data state (0). A memory cell may have the upper data state (1) having the high threshold voltage Vₜₕ according to resetting operation S10 shown in FIG. 1. The memory cell may be converted from the upper data state (1) to the lower data state (0) according to setting operation S20 shown in FIG. 1.

Therefore, resetting and setting operations S10 and S20 may be used to operate the SLC.

FIG. 3 is a graph illustrating a method of operating a multi level cell (MLC) according to example embodiments. Referring to FIG. 3, in a method of operating the MLC according to example embodiments, two bit data states may be indicated as (0,0), (0,1), (1,0) and (1,1). A threshold voltage Vₜₕ may be reduced in an order of the uppermost data state (1,1), the upper second data state (1,0), the lower second data state (0,1), and the lowest data state (0,0).

A memory cell may have the uppermost data state (1,1) having a highest threshold voltage Vₜₕ according to resetting operation S10 shown in FIG. 1. The memory cell may be converted from the uppermost data state (1,1) to the upper second data state (1,0) or the lower second data state (0,1) according to setting operation S20 shown in FIG. 1. Meanwhile, if setting operation S20 is repeated, the lower second data state (0,1) may be converted into the lowest data state (0,0).

Therefore, the MLC may be operated by performing resetting and setting operations S10 and S20 one or more times. In a method of operating the MLC according to example embodiments, a plurality of data states may be generated by controlling the amount of charges that may be removed from the charge storage layer of the memory cell in setting operation S20.

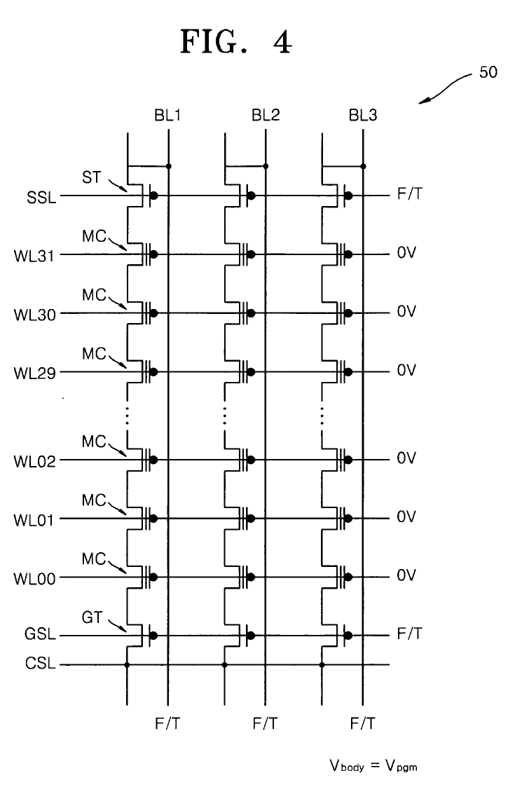

A method of operating a non-volatile memory device having a NAND structure block 50 will now be described with reference to FIGS. 4 through 6.

The block 50 may include a plurality of NAND type memory cells MCs that may be coupled to a plurality of bit lines BL1, BL2, and BL3 and a plurality of word lines WL00˜WL31. The memory cells MCs may have an NMOS structure. Hereinafter, operating conditions may be applied to NMOS structure memory cells MCs.

The word lines WL00˜WL31 may be disposed between a string select line SSL and a ground select line GSL. End portions of string select transistors STs may be connected to the bit lines BL1, BL2, and BL3. End portions of ground select transistors GTs may be connected to a common source line CSL. The number of the bit lines BL1, BL2, and BL3 and the word lines WL00˜WL31 may be properly selected according to the size of the block 50.

FIG. 4 is a circuit diagram of a nonvolatile memory device for explaining a resetting operation in a method of operating the nonvolatile memory device according to example embodiments. Referring to FIG. 4, a positive resetting voltage V_{pgm} may be applied to a body of the memory cells MCs. A voltage of 0V may be applied to the word lines WL00˜WL31. The bit lines BL1, BL2, and BL3, the string select line SSL, and the ground select line GSL may be floated. The resetting voltage V_{pgm} may be properly selected to allow tunneling of charges.

Therefore, charges may travel from control gate electrodes that may be coupled to the word lines WL00˜WL31 to charge storage layers, so that the memory cells MCs of the block 50 may be simultaneously reset.

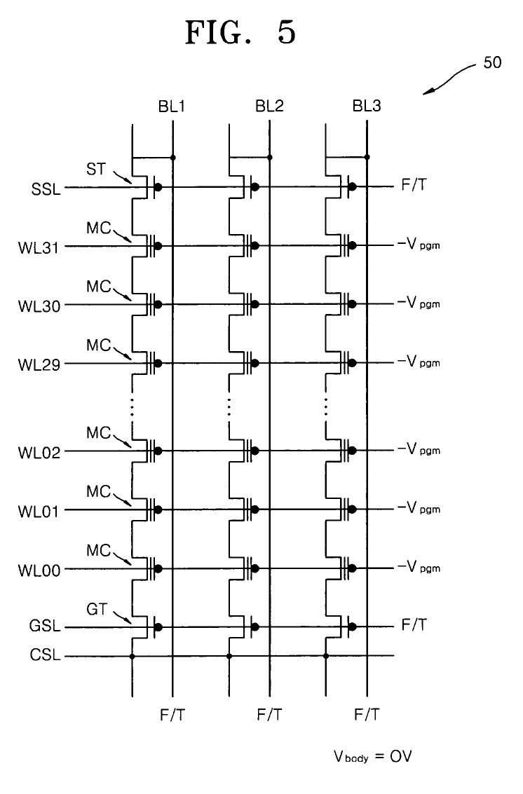

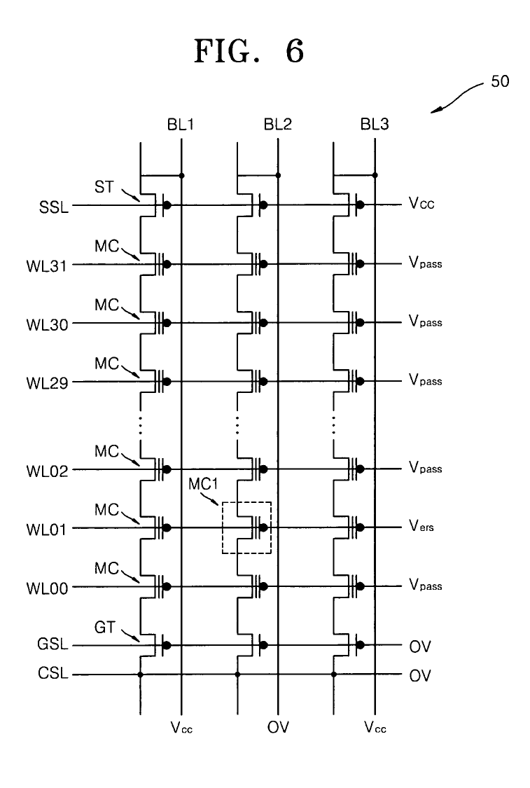

FIG. 5 is a circuit diagram of a nonvolatile memory device illustrating a resetting operation in a method of operating the nonvolatile memory device according to example embodiments. Referring to FIG. 5, 0V is may be applied to the body of the memory cells MCs. A negative resetting voltage −V_{pgm} may be applied to the word lines WL00˜WL31. The bit lines BL1, BL2, and BL3, the string select line SSL, and the ground select line GSL may be floated.

Therefore, charges may travel from control gate electrodes that may be coupled to the word lines WL00˜WL31 to charge storage layers, so that the memory cells MCs of the block 50 may be simultaneously reset.

FIG. 6 is a circuit diagram of a nonvolatile memory device illustrating a setting operation in a method of operating the nonvolatile memory device according to example embodiments. Referring to FIG. 6, an operation of setting the selected memory cell MC1 may be performed. A positive setting voltage Vₑᵣₛ may be applied to the word line WL01 that may be coupled to the selected memory cell MC1. A positive pass voltage Vₚₐₛₛ may be applied to the other word lines WL00 and WL02˜WL31. A voltage of 0V may be applied to the bit line BL2 that may be coupled to the selected memory cell MC1. A channel boosting voltage V_{cc} may be applied to the other bit lines BL1 and BL3. A voltage V_{cc} that may be the same as the channel boosting voltage V_{cc} may be applied to the string select line SSL. A voltage of 0V may be applied to the ground select line GSL.

The setting voltage Vₑᵣₛ may be properly selected to allow tunneling of charges. The pass voltage Vₚₐₛₛ may be properly selected to turn on the memory cells MCs. The channel boosting voltage V_{cc} may be properly selected to increase a body electric potential of the memory cells MCs.

Therefore, charges stored in charge storage layers of the selected memory cell MC1 may be removed, whereas charges stored in charge storage layers of the other memory cells MCs may be maintained. The memory cells MCs, which may be connected to the bit lines BL1 and BL3 to which the channel boosting voltage V_{cc} may be applied, may not be set.

The setting and setting prevention operations may be quite similar to general programming and programming preventing operations. However, charges may be injected in the general programming operation, whereas charges may be removed in the setting operation according to example embodiments. Similarly, charges may not be injected in the general programming prevention operation, whereas charges may not be removed in the setting operation according to example embodiments.

Therefore, the setting operation according to example embodiments may be performed in a similar manner to the general programming and erasing operations although both may be different in view of the objective.

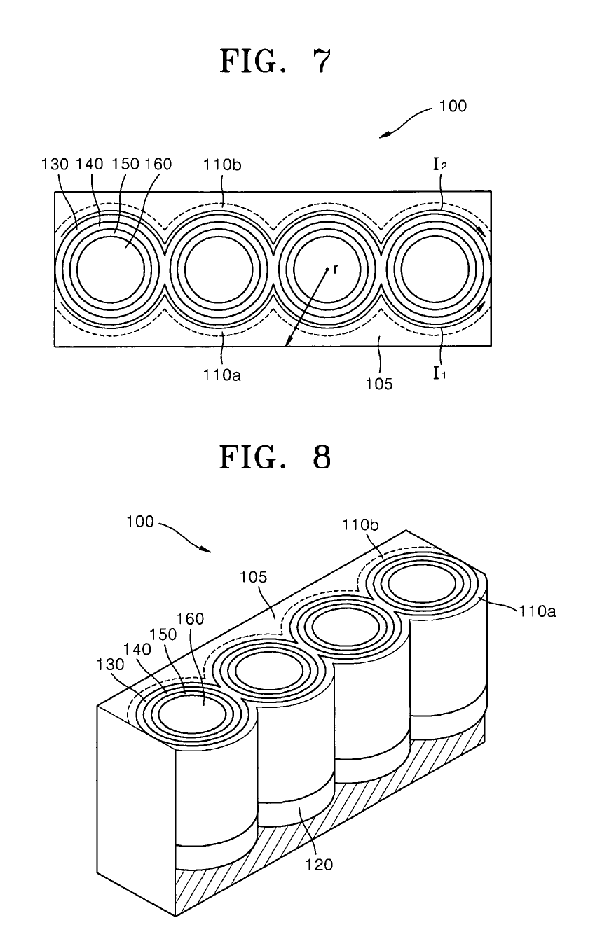

FIG. 7 is a plan view of a non-volatile memory device 100 illustrating a method of operating the non-volatile memory device 100 according to example embodiments. FIG. 8 is a partial perspective view of the non-volatile memory device 100 illustrated in FIG. 7.

Referring to FIGS. 7 and 8, a semiconductor substrate 105 may comprise a bulk semiconductor wafer, for example, a silicon wafer, a germanium wafer, or a silicon-germanium wafer. The semiconductor substrate 105 may further comprise a semiconductor epitaxial layer on the bulk semiconductor wafer.

A plurality of control gate electrodes 160 may be recessed, e.g. sunk, into the semiconductor substrate 105. The control gate electrodes 160 may be formed of polysilicon, metal, or metal silicide, for example. The control gate electrodes 160 may be cylindrically shaped and thus, may symmetrically induce radial electric fields.

However, because a current density may be reduced as the distance, r, between gate electrodes 160 and the semiconductor substrate 105 increases, the radial electric fields may be reduced. The smaller the radius of the control gate electrodes 160 is, the greater the reduction of the radial electric fields may be. Such a change in the radial electric fields may be compared to constant electric fields of a planar type non-volatile memory device.

The control gate electrodes 160 may also have oval or polygonal cylindrical shapes. In this case, the radial electric fields may not be constant.

A plurality of charge storage layers 140 may be disposed between sidewalls of the control gate electrodes 160 and the semiconductor substrate 105. The charge storage layers 140 may be one of, for example, charge trap type layers or floating node type layers. A plurality of tunnelling insulation layers 130 may be disposed between the semiconductor substrate 105 and the charge storage layers 140. A plurality of blocking insulation layers 150 may be disposed between the charge storage layers 140 and the control gate electrodes 160.

The tunnelling insulation layers 130, the charge storage layers 140, and the blocking insulation layers 150 may be formed around side walls of the control gate electrodes 160. In more detail, the blocking insulation layers 150 may surround the control gate electrodes 160, the charge storage layers 140 may surround the blocking insulation layers 150, and the tunnelling insulation layers 130 may surround the charge storage layers 140. Accordingly, the tunnelling insulation layers 130, the charge storage layers 140, and the blocking insulation layers 150 may have hollow tube shapes.

A pair of tunnelling insulation layers 130 may contact each other. Thus, the semiconductor substrate 105 may be separated into an upper region above the tunnelling insulation layers 130 and a lower region below the tunnelling insulation layers 130. The upper and lower regions may be referred to as first and second regions, respectively. However, according to example embodiments, the upper and lower regions may have alternate titles.

First and second channel regions 110a and 110b may not be limited to two regions of the semiconductor substrate 105 below the tunnelling insulation layers 130 and may be separated by the tunnelling insulation layers 130. For example, the first channel regions 110a may be limited to the lower region (the first region) of the semiconductor substrate 105, and the second channel regions 110b may be limited to the upper region (the second region) of the semiconductor substrate 105.

Alternatively, buried insulation layers 120 may be disposed between the bottom of the control gate electrodes 160 and the semiconductor substrate 105. The thickness of the buried insulation layers 120 may be greater than that of the tunnelling insulation layers 130 and the blocking insulation layers 150 so that channels may not be formed on the bottom of the semiconductor substrate 105. Therefore, the first and second channel regions 110a and 110b may not be connected to each other through the bottom of the semiconductor substrate 105.

The tunnelling insulation layers 130 may be connected to each other so that the first channel regions 110a may be continuously connected to each other and the second channel regions 110b may be continuously connected to each other. Therefore, the first channel regions 110a may be continuously connected to each other without source and drain regions and may allow the flow of a first current 11. Similarly, the second channel regions 110b may be continuously connected to each other without source and drain regions and may allow the flow of a second current 12.

The first channel regions 110a and the second channel regions 110b may be respectively connected without source and drain regions since the control gate electrodes 160 may have radial electric fields. Therefore, the non-volatile memory device 100 may have a NAND structure in which source and drain regions may be omitted so that an area of the NAND structure may be greatly reduced compared to a conventional NAND structure and thus the non-volatile memory device 100 may be highly integrated.

The first channel regions 110a and the second channel regions 110b may be connected to bit lines. The control gate electrodes 160 may be used as common word lines. The operation of the non-volatile memory device 100 may be performed by controlling the bit lines and the word lines to use tunnelling of charges through the blocking insulation layers 150. The tunnelling of charges through the blocking insulation layers 150 may be contrasted with tunnelling of charges through the tunnelling insulation layers 130.

Tunnelling of charges through the blocking insulation layers 150 may be selected instead of tunnelling of charges through the tunnelling insulation layers 130 due to the structure and distribution of electric fields of the non-volatile memory device 100. The tunnelling insulation layers 130 may occupy a larger portion of non-volatile memory device 100 than that occupied by the blocking insulation layers 150. If a voltage is applied to the control gate electrodes 160 the blocking insulation layers 150 may induce higher electric fields than the tunnelling insulation layers 130 because the radial electric fields may be reduced as the distance, r, between gate electrodes 160 and the semiconductor substrate 105 increases. The distribution of electric fields may be contrary to that of a planar type non-volatile memory device which may have constant electric fields with regard to the same material.

The charge storage layers 140 may have ring shapes but their portions contacting the first channel regions 110a and the second channel regions 110b may be local charge storage layers. The charge storage layers 140 may be charge trap type layers. Therefore, the non-volatile memory device 100 may process 2 bit data in an SLC operation mode.

The operations of resetting and setting the non-volatile memory device 100 may be described with reference to FIGS. 4 through 6. For example, the non-volatile memory device 100 may be reset by applying a negative resetting voltage to the control gate electrodes 160 or applying a positive resetting voltage to the semiconductor substrate 105, so that charges may be injected into the charge storage layers 140.

The non-volatile memory device 100 may be set by applying a positive setting voltage to one or more selected control gate electrodes 160. Furthermore, 0V may be applied to one of the first channel regions 110a and the second channel regions 110b and a channel boosting voltage may be applied to the other. Therefore, charges may be removed from the charge storage layers 140 in a direction in which 0V may be applied to one of the first channel regions 110a and the second channel regions 110b (the setting operation). Additionally, charges of the charge storage layers 140 may be maintained in a direction in which the channel boosting voltage is applied to another one of the first channel regions 110a and the second channel regions 110b (the setting prevention operation).

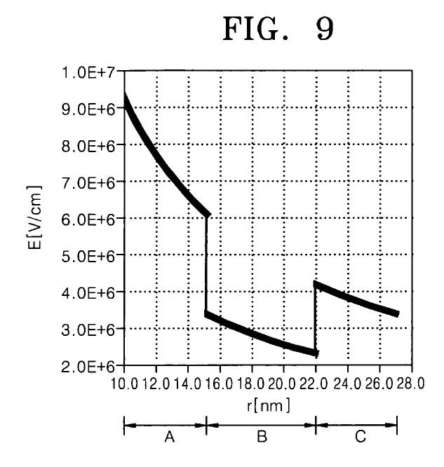

FIG. 9 is a graph illustrating the distribution of electric fields in an operation of setting the nonvolatile memory device 100 illustrated in FIGS. 7 and 8. The graph shows a simulation result under the following conditions. First, in this example, second, and third regions A, B, and C are the blocking insulation layers 150, the charge storage layers 140, and the tunnelling insulation layers 130, respectively. In this example, the blocking insulation layers 150 are silicon oxide layers having a dielectric constant of about 3.9, the charge storage layers 140 are silicon nitride layers, the tunnelling insulation layers 130 are silicon oxide layers having a dielectric constant of about 3.9, and a positive voltage is applied to the control gate electrodes 160.

Referring to FIG. 9, electric fields E of the blocking insulation layers 150 may be greater than that of the tunnelling insulation layers 130. Generally, about 8˜10 MV/cm of electric fields E may be necessary for tunnelling of charges. However, the electric fields E of the tunnelling insulation layers 130 may be about 4 MV/cm so that the tunnelling of charges through the tunnelling insulation layers 130 may be impossible. As a result, it may be difficult to perform the operation of setting the nonvolatile memory device 100 through the tunnelling insulation layers 130.

However, the electric fields E of the blocking insulation layers 150 may be about 6˜9 MV/cm so that the tunnelling of charges through the blocking insulation layers 150 may be possible. Voltages as low as 7 and 8 V may be applied to the control gate electrode 160. Therefore, the nonvolatile memory device 100 may be operated at a voltage much lower than the 15˜20 V range which may be necessary for a conventional planar type non-volatile memory device.

According to the method of operating the nonvolatile memory device 100, it may be possible to set and reset the nonvolatile memory device 100 at a low voltage by using the tunneling through the blocking insulation layers 150. Inverse tunnelling may be almost impossible through the tunnelling insulation layers 130, thus the reliability of the setting and resetting operations may be improved.

The method of operating the nonvolatile memory device 100 according to example embodiments may be applied to a nonvolatile memory device having a recess type structure having source and drain regions, which may be different from the nonvolatile memory device 100. The method of operating the nonvolatile memory device 100 according to example embodiments may be applied when electric fields of blocking insulation layers may be greater than that of tunnelling insulation layers.

In a method of operating a nonvolatile memory device according to example embodiments, tunneling via a blocking insulation layer at a low voltage may make it possible to perform resetting and setting operations. In particular, since an injection of charges into a charge storage layer may enable a resetting operation to be performed, operation utilities which are used in a general planar type structure may be applied for operating a nonvolatile memory device according to example embodiments, thereby increasing the operation reliability of a three-dimensional non-volatile memory device.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of operating a nonvolatile memory device comprising:
resetting the nonvolatile memory device by injecting charges into one or more layers of the nonvolatile memory device; and
setting the nonvolatile memory device by removing at least some of the charges from the one or more layers of the nonvolatile memory device.

2. The method of claim 1, wherein
the nonvolatile memory device is reset by injecting the charges into charge storage layers of a plurality of memory cells; and
the nonvolatile memory device is set by removing at least some of the charges from the charge storage layers of one or more selected memory cells from among the plurality of memory cells.

3. The method of claim 2, wherein the resetting of the nonvolatile memory device comprises applying a negative resetting voltage to control gate electrodes of the plurality of memory cells.

4. The method of claim 2, wherein the resetting of the nonvolatile memory device further comprises applying a positive resetting voltage to bodies of the plurality of memory cells.

5. The method of claim 2, wherein the setting of the nonvolatile memory device comprises applying a positive setting voltage to control gate electrodes of the one or more selected memory cells.

6. The method of claim 2, wherein the plurality of memory cells is coupled to a plurality of bit lines and a plurality of word lines in a NAND structure.

7. The method of claim 6, wherein the setting of the nonvolatile memory device further comprises applying a voltage of 0V to one or more selected bit lines from among the plurality of bit lines, the one or more selected bit lines being coupled to the one or more selected memory cells, and applying a channel boosting voltage to bit lines, from among the plurality of bit lines, other than the one or more selected bit lines.

8. The method of claim 6, wherein the setting of the nonvolatile memory device further comprises applying a setting voltage to one or more selected word lines, from among the plurality of word lines, the one or more selected word lines being coupled to the one or more selected memory cells, and applying a pass voltage to word lines, from among the plurality or word lines, other than the one or more selected word lines.

9. The method of claim 2, wherein the setting of the nonvolatile memory device further comprises controlling an amount of the charges removed from the charge storage layers of the one or more selected memory cells, and generating a plurality of data states.

10. The method of claim 2, wherein the setting and resetting of the nonvolatile memory device further comprise tunneling the charges between the charge storage layers and control gate electrodes that are coupled to the charge storage layers.

11. The method of claim 1, wherein
the nonvolatile memory device includes a semiconductor substrate,
a plurality of control gate electrodes recessed into the semiconductor substrate,
a plurality of tunneling insulation layers disposed between a plurality of charge storage layers and the semiconductor substrate, pairs of adjacent tunneling insulation layers contacting each other and separating the semiconductor substrate into first and second regions, and
a plurality of blocking insulation layers disposed between the plurality of charge storage layers and the plurality of control gate electrodes; and wherein
the nonvolatile memory device is reset by injecting the charges into the plurality of charge storage layers, and
the nonvolatile memory device is set by removing at least some of the charges from one or more selected charge storage layers from among the plurality of charge storage layers.

12. The method of claim 11, wherein the resetting of the nonvolatile memory device comprises using tunneling of the charges through the plurality of blocking insulation layers.

13. The method of claim 12, wherein the resetting of the nonvolatile memory device comprises applying a negative resetting voltage to the plurality of control gate electrodes.

14. The method of claim 12, wherein the resetting of the nonvolatile memory device further comprises applying a positive setting voltage to the semiconductor substrate.

15. The method of claim 11, wherein the setting of the nonvolatile memory device comprises using tunneling of the charges through one or more selected blocking insulation layers, from among the plurality of blocking insulation layers, the selected blocking insulation layers being disposed on the one or more selected charge storage layers.

16. The method of claim 15, wherein the setting of the nonvolatile memory device further comprises applying the positive setting voltage to one or more selected control gate electrodes, from among the plurality of control gate electrodes, the selected control gate electrodes being disposed on the one or more selected charge storage layers.

17. The method of claim 16, wherein the setting of the nonvolatile memory device further comprises applying a pass voltage to control gate electrodes, from among the plurality of control gate electrodes, other than the selected control gate electrodes.

18. The method of claim 11, wherein the charge storage layers are charge-trap layers.

19. The method of claim 18, wherein the setting of the nonvolatile memory device further comprises applying a voltage of 0V to bit lines coupled to the first region and applying a channel boosting voltage to bit lines coupled to the second region.

20. The method of claim 18, wherein the setting of the nonvolatile memory device further comprises applying a voltage of 0V to bit lines coupled to the second region and applying a channel boosting voltage to bit lines coupled to the first region.
